(19) United States
(12) Patent Application Publication
(10) Pub. No.: US 2008/0296677 A1
(43) Pub. Date: Dec. 4, 2008

(54) SEMICONDUCTOR DEVICE AND METHOD OF MANUFACTURING THE SAME AND DATA PROCESSING SYSTEM

(75) Inventor: Yoshihiro TAKAISHI, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC, Tokyo (JP)

(21) Appl. No.: 12/130,211

(22) Filed: May 30, 2008

(30) Foreign Application Priority Data
May 31, 2007 (JP) 2007-144975

(51) Int. Cl. H01L 29/78; H01L 21/4763

(52) U.S. Cl. 257/336; 438/585; 257/E29.268

(57) ABSTRACT

A semiconductor device is provided with a silicon pillar formed substantially perpendicularly to a main surface of a substrate, a gate electrode covering side surface of the silicon pillar via a gate insulation film, a conductive layer provided on an upper part of the silicon pillar, a cylindrical sidewall insulation film intervening between the conductive layer and the gate electrode so as to insulate therebetween. An inner wall of the side wall insulation film is in contact with the conductive layer, and an outer wall of the side wall insulation film is in contact with the gate electrode.

### TECHNICAL FIELD

The present invention relates to a semiconductor device and a method of manufacturing the same, and more particularly relates to a semiconductor device having a vertical transistor using a silicon pillar, and a method of manufacturing the semiconductor device. The present invention also relates to a data processing system including semiconductor device having a vertical transistor using a silicon pillar.

### BACKGROUND OF THE INVENTION

The integration of the semiconductor device has hitherto been achieved mainly by miniaturizing transistors. However, miniaturization of transistors has come to the limit, and when the transistors are attempted to be more miniaturized, there is a risk that the semiconductor device does not operate correctly due to the short-channel effect and the like.

As a method of basically solving this problem, there has been proposed a method of three-dimensionally processing a semiconductor substrate, thereby three-dimensionally forming a transistor. A three-dimensional transistor using a silicon pillar extending perpendicularly to the main surface of the semiconductor substrate as a channel has an advantage in that an occupied area is small and that a large drain current is obtained by a complete depletion. This three-dimensional transistor can be also used for a closest layout of 4F² (see Japanese Patent Application Laid-open Nos. 2003-303901, H5-136374, H6-209089, H9-8295, and 2002-83945).

In a vertical transistor using a silicon pillar, a gate electrode is positioned on the side surface of the silicon pillar, and a diffusion layer becoming a source or a drain is formed on the upper part of the silicon pillar. Therefore, a channel length of the transistor is decided by a height of the gate electrode formed on the side surface of the silicon pillar. However, if the gate electrode is processed by photolithography, the height of the gate electrode fluctuates. Further, relationship between positions of the gate electrode and the diffusion layer in the silicon pillar also fluctuates. As a result, a problem that transistor characteristics fluctuate occurs accordingly.

In a vertical transistor using a silicon pillar, a through hole that exposes the upper portion of the silicon pillar should be formed in accurate. However, it is difficult to expose the upper portion of the silicon pillar because a planar area of the silicon pillar is designed very small. Therefore, a short-circuiting between the gate electrode and conductive layer to be isolated from the gate electrode formed above the silicon pillar may occur, for example. This results in deterioration of reliability of products.

### SUMMARY OF THE INVENTION

It is therefore an object of the present invention to provide an improved semiconductor device having a vertical transistor using a silicon pillar and a method of manufacturing the same.

Another object of the present invention is to provide a semiconductor device having a vertical transistor using a silicon pillar and having desired transistor characteristics, and a method of manufacturing the same.

Still another object of the present invention is to provide a semiconductor device having a vertical transistor using a silicon pillar and capable of forming an opening on the upper part of the silicon pillar in self-alignment, and a method of manufacturing the same.

Still another object of the present invention is to provide a semiconductor device having a vertical transistor using a silicon pillar and capable of forming a conductive film on the upper part of the silicon pillar in self-alignment, and a method of manufacturing the same.

Still another object of the present invention is to provide a data processing system including such a semiconductor device.

The above and other objects of the present invention can be accomplished by a semiconductor device comprising a silicon pillar formed substantially perpendicularly to a main surface of a substrate, a gate electrode covering side surface of the silicon pillar via a gate insulation film, a conductive layer provided on an upper part of the silicon pillar, a cylindrical sidewall insulation film intervening between the conductive layer and the gate electrode so as to insulate therebetween.

According to the semiconductor device of the present invention, substantially entire side surface of the silicon pillar can be covered by the gate electrode because the conductive layer formed on the upper part of the silicon pillar and the gate electrode formed on the side surface of the silicon pillar are separated by the cylindrical sidewall insulation film. As a result, a channel length substantially coincides with the height of the silicon pillar, whereby the transistor characteristics can be stable.

The above and other objects of the present invention can also be accomplished by a method of manufacturing a semiconductor device comprising: a first step of forming a silicon pillar substantially perpendicularly to a main surface of a substrate by using a hardmask; a second step of forming a gate insulation film on a side surface of the silicon pillar without removing the hardmask; a third step of forming a gate electrode covering a side surface of the silicon pillar via the gate insulation film without removing the hardmask; a fourth step of removing the hardmask remaining on a upper part of the silicon pillar, thereby forming the through-hole; a fifth step of forming a sidewall insulation film on a inside wall of the through-hole; and a sixth step of forming conductive layer in the region having a cylindrical shape and surrounded by the sidewall insulation film.

According to the present invention, since the opening is formed on the upper part of the silicon pillar by removing the hardmask using for forming the silicon pillar, the conductive layer be formed in self-aligning to the silicon pillar.

Further, even if the planar size of the silicon pillar is very small, the silicon pillar and the upper wiring can be connected reliably.

Furthermore, a insulation between the gate electrode and the conductive film formed on the upper part of the silicon pillar can be ensure reliably.

As explained above, according to the present invention, stable transistor characteristics and highly reliability can be ensured.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1A is a schematic cross-sectional view and a schematic top plan view showing a structure of a semiconductor device according to a preferred embodiment of the present invention;

FIG. 1B is a schematic top plan view showing a structure of a semiconductor device according to a preferred embodiment of the present invention;

FIG. 2A is a schematic cross-sectional view showing a process for manufacturing the semiconductor device 10 according to the present embodiment (specifically forming STI 12 and active regions 13);

FIG. 2B is a schematic top plan view for showing a process for manufacturing the semiconductor device 10 according to the present embodiment (specifically forming STI 12 and active regions 13);

FIG. 3A is a schematic cross-sectional view showing a process for manufacturing the semiconductor device 10 according to the present embodiment (specifically forming a hardmask 14);

FIG. 3B is a schematic top plan view for showing a process for manufacturing the semiconductor device 10 according to the present embodiment (specifically forming a hardmask 14);

FIG. 4A is a schematic cross-sectional view showing a process for manufacturing the semiconductor device 10 according to the present embodiment (specifically patterning the hardmask 14);

FIG. 4B is a schematic top plan view for showing a process for manufacturing the semiconductor device 10 according to the present embodiment (specifically patterning the hardmask 14);

FIG. 5 is a schematic cross-sectional view showing a process for manufacturing the semiconductor device 10 according to the present embodiment (specifically forming silicon pillars 15a, 15b);

FIG. 6 is a schematic cross-sectional view showing a process for manufacturing the semiconductor device 10 according to the present embodiment (specifically forming sidewall insulation film 16);

FIG. 7 is a schematic cross-sectional view showing a process for manufacturing the semiconductor device 10 according to the present embodiment (specifically forming silicon oxide film 17);

FIG. 8 is a schematic cross-sectional view showing a process for manufacturing the semiconductor device 10 according to the present embodiment (specifically forming first diffusion layer 18);

FIG. 9 is a schematic cross-sectional view showing a process for manufacturing the semiconductor device 10 according to the present embodiment (specifically removing the sidewall insulation film 16);

FIG. 10 is a schematic cross-sectional view showing a process for manufacturing the semiconductor device 10 according to the present embodiment (specifically forming gate insulation films 19A, 19B);

FIG. 11 is a schematic cross-sectional view showing a process for manufacturing the semiconductor device 10 according to the present embodiment (specifically forming a polycrystalline silicon film);

FIG. 12A is a schematic cross-sectional view showing a process for manufacturing the semiconductor device 10 according to the present embodiment (specifically etching back the polycrystalline silicon film);

FIG. 12B is a schematic plan view showing a process for manufacturing the semiconductor device 10 according to the present embodiment (specifically etching back the polycrystalline silicon film);

FIG. 13 is a schematic cross-sectional view showing a process for manufacturing the semiconductor device 10 according to the present embodiment (specifically forming an interlayer insulation film 21);

FIG. 14 is a schematic cross-sectional view showing a process for manufacturing the semiconductor device 10 according to the present embodiment (specifically forming a mask oxide film 22);

FIG. 15A is a schematic cross-sectional view showing a process for manufacturing the semiconductor device 10 according to the present embodiment (specifically patterning the mask oxide film 22);

FIG. 15B is a schematic plan view showing a process for manufacturing the semiconductor device 10 according to the present embodiment (specifically patterning the mask oxide film 22);

FIG. 16A is a schematic cross-sectional view showing a process for manufacturing the semiconductor device 10 according to the present embodiment (specifically removing a silicon nitride film 14b);

FIG. 16B is a schematic plan view showing a process for manufacturing the semiconductor device 10 according to the present embodiment (specifically removing a silicon nitride film 14b);

FIG. 17 is a schematic cross-sectional view showing a process for manufacturing the semiconductor device 10 according to the present embodiment (specifically forming LDD region 24);

FIG. 18A is a schematic cross-sectional view showing a process for manufacturing the semiconductor device 10 according to the present embodiment (specifically forming sidewall insulation film 25);

FIG. 18B is a schematic plan view showing a process for manufacturing the semiconductor device 10 according to the present embodiment (specifically forming sidewall insulation film 25);

FIG. 19A is a schematic cross-sectional view showing a process for manufacturing the semiconductor device 10 according to the present embodiment (specifically forming an opening);

FIG. 19B is a schematic plan view showing a process for manufacturing the semiconductor device 10 according to the present embodiment (specifically forming an opening);

FIG. 20A is a schematic cross-sectional view showing a process for manufacturing the semiconductor device 10 according to the present embodiment (specifically forming a silicon epitaxial layer 26a);

FIG. 20B is a schematic plan view showing a process for manufacturing the semiconductor device 10 according to the present embodiment (specifically forming a silicon epitaxial layer 26a);

FIG. 21A is a schematic cross-sectional view showing a process for manufacturing the semiconductor device 10 according to the present embodiment (specifically forming second diffusion layer 26);

FIG. 21B is a schematic plan view showing a process for manufacturing the semiconductor device 10 according to the present embodiment (specifically forming second diffusion layer 26);

FIG. 22 is a schematic cross-sectional view showing a process for manufacturing the semiconductor device 10 according to the present embodiment (specifically forming interlayer insulating layer 27);

FIG. 23A is a schematic cross-sectional view showing a process for manufacturing the semiconductor device 10 according to the present embodiment (specifically forming contact-holes 28a to 28c);

FIG. 23B is a schematic plan view showing a process for manufacturing the semiconductor device 10 according to the present embodiment (specifically forming contact-holes 28a to 28c);

FIG. 24A is a schematic cross-sectional view showing a process for manufacturing the semiconductor device 10 according to the present embodiment (specifically forming contact-plugs 29a to 29c);

FIG. 24B is a schematic plan view showing a process for manufacturing the semiconductor device 10 according to the present embodiment (specifically forming contact-plugs 29a to 29c);

FIG. 25 is a schematic cross-sectional view showing a structure of a semiconductor device according to another preferred embodiment of the present invention;

FIG. 26 is a schematic cross-sectional view showing a semiconductor device according to another preferred embodiment of the present invention; and

FIG. 27 is a block diagram showing a configuration of a data processing system 100 using a semiconductor device according to the preferred embodiment of the present invention.

### DETAILED DESCRIPTION OF THE EMBODIMENTS

Preferred embodiments of the present invention will now be described in detail hereinafter with reference to the accompanying drawings.

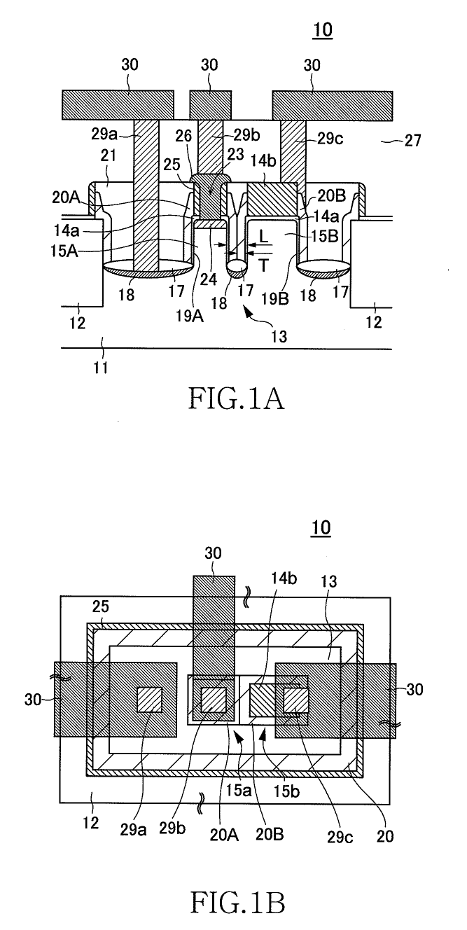

FIGS. 1A and 1B are a schematic cross-sectional view and a schematic top plan view, respectively showing a structure of a semiconductor device 10 according to a preferred embodiment of the present invention.

As shown in FIGS. 1A and 1B, the semiconductor device 10 according to the present embodiment is a vertical transistor using a silicon pillar, and includes an STI (Shallow Trench Isolation) 12 formed on a silicon substrate 11, first and second silicon pillars 15A and 15B formed in an active region encircled by the STI 12, a first gate electrode 20A covering a side surface of the first silicon pillar 15A via a first gate insulation film 19A, and a second gate electrode 20B covering a side surface of the second silicon pillar 15B via a second gate insulation film 19B. The semiconductor device 10 also includes a first diffusion layer 18 provided at a lower part of the first and second silicon pillars 15A and 15B, and a second diffusion layer 26 provided at an upper part of the second silicon pillar 15B. A first diffusion layer 18 is not positioned in a region right below the first and second silicon pillars 15A and 15B, but is positioned in a flat region of the silicon substrate 11 not covered with a silicon pillar.

The first diffusion layer 18 is connected to a wiring layer 30 via a first contact-plug 29a. The second diffusion layer 26 is connected to the wiring layer 30 via a second contact-plug 29b. A gate electrode 20 is connected to the wiring layer 30 via a third contact-plug (gate contact) 29c.

The first silicon pillar 15A is a transistor pillar, and the second silicon pillar 15B is a gate electrode pillar (dummy pillar). The first and second silicon pillars 15A and 15B are formed substantially perpendicularly to the main surface of the silicon substrate 11. A distance L between the two silicon pillars is set smaller than two times a thickness T of the gate electrode. By laying out the first and second silicon pillars 15A and 15B to close to each other in this way, the first gate electrode 20A formed on the side surface of the first silicon pillar 15B and the second gate electrode 20B formed on the side surface of the second silicon pillar 15B can be brought into contact with other, thereby ensuring an electric connection to each other.

Preferably, a size of the second silicon pillar 15B in the plane direction is set larger than that of the first silicon pillar 15A. While not particularly limited, preferably, a flat surface size of the first silicon pillar is set to about 70×70 nm, and a flat surface size of the second silicon pillar is set to about 100×70 nm. Accordingly, a distance between the second contact-plug 29b and the gate contact 29c can be increased, and therefore, a formation margin of the wiring layer 30 can be increased. Further, the plane region of the second gate electrode 20B at the second silicon pillar 15B increases, and therefore, the second gate electrode 20B can be securely connected to the gate contact 29c. The height of each silicon pillar can be set correspondingly to the required transistor characteristic. For example, when the plane size of the first silicon pillar is 70×70 nm, the height of each silicon pillar can be set to about 100 nm.

The first gate electrode 20A is formed on a side surface of the first silicon pillar 15A via the first gate insulation film 19A. An upper peripheral part of the first silicon pillar 15A is in contact with a protection insulation film 14a, and an upper center part of the first silicon pillar 15A is opened as a through-hole 23. On the other hand, a side surface and an upper surface of the second silicon pillar 15B are completely covered by the second gate insulation film 19B and the protection insulation film 14a. However, the second gate insulation film 19B is a dummy insulation film simultaneously formed with the first gate insulation film 19A, and functions as an insulation film, not as a gate insulation film of the transistor. The protection insulation film 14a is a part of a mask to form the first silicon pillar 15A and the second silicon pillar 15B, and includes a silicon oxide film.

A cap insulation film 14b is provided on an upper surface of the second gate electrode 20B. The cap insulation film 14b is a hardmask used to form the first and second silicon pillars 15A and 15B, and is also used as the insulation film without being removed in the subsequent process. A hardmask was also present above the first silicon pillar 15A, and was removed at the time of forming the through-hole 23 as the space to form the second diffusion layer 26.

The first and second gate electrodes 20A and 20B are formed on the external periphery of the corresponding gate insulation films 19A and 19B. Particularly, the second gate electrode 20B has a ring-shaped upper region covering the peripheral part of the cap insulation film 14b, and the gate contact 29c is connected to this upper region. More specifically, the gate contact 29c is connected to an interface between the cap insulation film 14b and the second gate electrode 20B remaining on the upper part of the second silicon pillar 15.

The first diffusion layer 18 is provided on a bottom part of an active region 13, that is, on the lower periphery of the first silicon pillar 15A. A conductive material used as the second diffusion layer 26 is embedded into the through-hole 23 provided on the upper part of the first silicon pillar 15A. The first and second diffusion layers 18 and 26 can be formed by ion-implanting an impurity having conductivity type opposite to that of an impurity in the silicon substrate.

The second diffusion layer 26 is connected to an LDD (Lightly Doped Drain) region 24 formed on the upper part of the first silicon pillar 15A via the through-hole 23 piercing through the insulation films 14a and 21. A cylindrical sidewall insulation film 25 intervening between the second diffusion layer 26 and the first gate electrode 20A is formed on an inner wall surface of the through-hole 23, thereby securing insulation between the second diffusion layer 26 and the first gate electrode 20A. Thus, the side surfaces of the first silicon pillar 15A are substantially entirely covered with the first gate electrode 20A.

In the present embodiment, a planar position of the external periphery of the sidewall insulation film 25 and planar position of the external periphery of the first silicon pillar 15A substantially coincides with each other. This is because the sidewall insulation film 25 is formed within the through-hole 23 formed by removing a hardmask (corresponding to the cap insulation film 14b) used to form the silicon pillar, and because the size of the silicon pillar 15A approximately coincides with the size of the through-hole 23. This means that the space formed by removing the hardmask used to form the silicon pillar is used as a space to form the second diffusion layer 26.

The first to third contact-plugs 29a to 29c are formed by filling a conductive material into the contact-hole piercing through an interlayer insulation film 27. Polycrystalline silicon is preferably used for the material of the contact-plug. A lower end of the gate contact 29c is connected to an interface between the cap insulation film 14b and the second gate electrode 20B at the upper part of the second silicon pillar 15B.

In the semiconductor device 10 having the above configuration, the first diffusion layer 18 functions as one of a source and a drain, and the second diffusion layer 26 functions as the other of the source and the drain. The first gate electrode 20A is connected to the gate contact 29c through the second gate electrode 20B, and is further connected to the wiring layer 30. A channel region is formed in a vertical direction of the silicon pillar, and is controlled by an electric field from the first gate electrode 20A via the gate insulation film 19A.

As explained above, according to the semiconductor device 10 of the present embodiment, a channel length of the transistor is coincident with the height of the first silicon pillar 15 because the side surfaces of the first silicon pillar 15A are substantially entirely covered with the first gate electrode 20A. Thus, designed characteristics of transistors can be obtained. Moreover, because the side wall insulation film 25 intervenes between the second diffusion layer 26 and the first gate electrode 20A, a short-circuiting therebetween cannot occur.

Further, according to the semiconductor device 10 of the present embodiment, the second silicon pillar 15B as a dummy pillar is provided adjacently to the first silicon pillar 15A as a transistor pillar. The first gate electrode 20A and the gate contact 29c are connected to each other via the second gate electrode 20B formed on the side surface of the second silicon pillar 15B. Therefore, a gate electrode structure capable of being easily connected to the gate contact can be provided, without performing photolithography to form a flat part of the gate electrode.

Furthermore, according to the present embodiment, a distance between the first silicon pillar 15A and the second silicon pillar 15B is set smaller than two times a film thickness of the gate electrode. Therefore, an electric connection can be securely obtained between the first gate electrode 20A at the first silicon pillar 15A side and the second gate electrode 20B at the second silicon pillar 15B side. Further, according to the present embodiment, the second diffusion layer 26 is provided within the through-hole 23 formed by removing a hardmask used to form the first silicon pillar 15A. Therefore, the second diffusion layer 26 can be formed in self-alignment to the first silicon pillar 15A, and consequently, the first silicon pillar 15A can be securely connected to the second diffusion layer 26.

A method of manufacturing the semiconductor device 10 according to the present embodiment is explained in detail below.

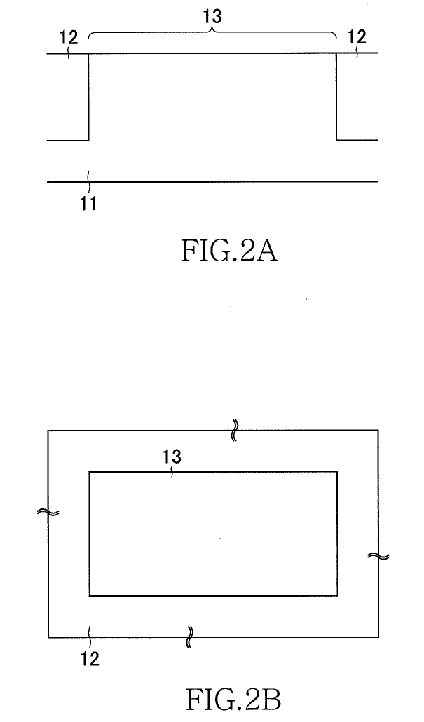

FIG. 2A to FIG. 24B are process diagrams for explaining a method of manufacturing the semiconductor device 10 according to the present embodiment, wherein FIG. 2A is a cross-sectional view and FIG. 2B is a top plan view.

In manufacturing the semiconductor device 10, the silicon substrate 11 is first prepared, and the STI 12 is formed on the silicon substrate 10, thereby forming an active region 13 encircled by the STI 12 (FIGS. 2A and 2B). While many active regions are actually formed on the silicon substrate 11, only one active region is shown in FIGS. 2A and 2B. While not particularly limited, the active region 13 has a rectangular shape in the present embodiment.

In forming the STI 12, a trench having a depth of about 220 nm is formed on the main surface of the silicon substrate 11 by dry etching, and a thin silicon oxide film is formed by thermal oxidation at about 100° C. on the entire surface of the substrate including the inner wall of the trench. Thereafter, a silicon oxide film having a thickness of 400 to 500 nm is deposited on the entire surface of the substrate including the inside of the trench, by the CVD (Chemical Vapor Deposition) method. Thereafter, an unnecessary silicon oxide film on the silicon substrate 11 is removed by CMP (Chemical Mechanical Polishing), and the silicon oxide film is left only within the trench, thereby forming the STI 12.

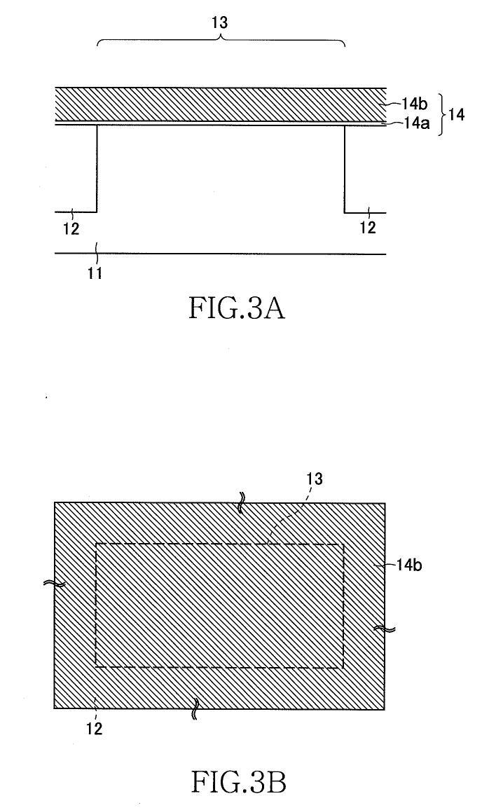

Next, the first and second silicon pillars 15A and 15B are formed simultaneously within the active region 13. In forming the silicon pillars 15A and 15B, the silicon oxide film 14a as a protection insulation film and the silicon nitride film 14b as a hardmask are formed on the entire surface of the substrate (FIGS. 3A and 3B). While not particularly limited, the silicon oxide film 14a and the silicon nitride film 14b can be formed by the CVD method. Preferably, the silicon oxide film 14a has a thickness of about 5 nm, and the silicon nitride film 14b has a thickness of about 120 nm. In the present specification, a lamination film of the silicon nitride film 14a and the silicon nitride film 14b is also simply called a “hardmask 14”.

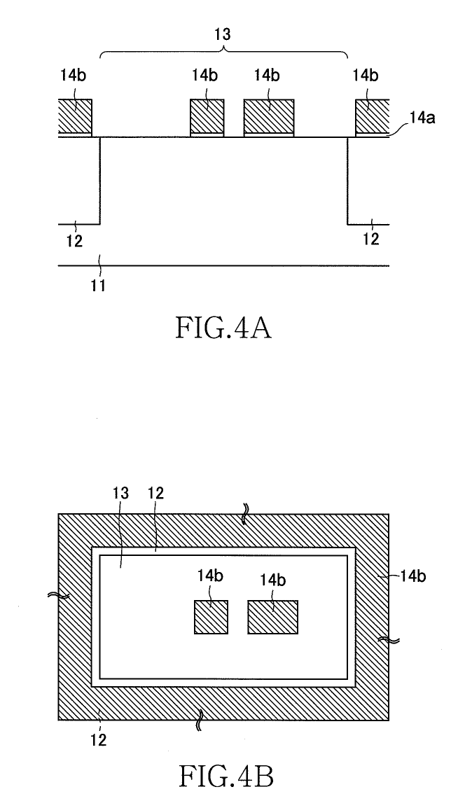

Thereafter, the hardmask 14 is patterned, thereby leaving the hardmask 14 in the region in which the first and second silicon pillars 15A and 15B are to be formed and in the region at the outside of the active region 13, and removing other regions (FIGS. 4A and 4B). The edge of the hardmask 14 covering the STI 12 is preferably positioned at the outside of the external periphery of the active region 13 to avoid forming an unnecessary silicon pillar within the active region 13.

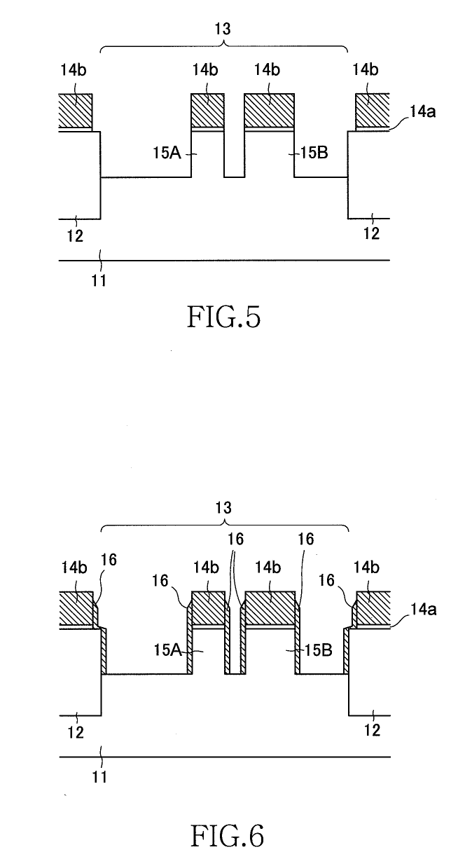

Further, the exposed surface of the active region 13 is etched by dry etching, using the hardmask 14 patterned in this way (FIG. 5). By this etching process, a recess is shaped on the exposed surface of the active region 13, and parts not etched become the first and second silicon pillars 15A and 15B substantially perpendicular to the main surface of the silicon substrate. The hardmask 14 remaining on the upper part of the silicon pillars 15A and 15B become cap insulation films.

Next, a sidewall insulation film 16 is formed on the side surfaces of the first and second silicon pillars 15A and 15B (FIG. 6). The sidewall insulation film 16 can be formed by protecting the exposed surface of the active region 13 thermal oxidation without removing the hardmask 14, then forming a silicon nitride film, and etching back this silicon nitride film. Accordingly, the internal peripheral surface of the active region 13 and the side surfaces of the first and second silicon pillars 15A and 15B become in the state of being covered by the sidewall insulation film 16.

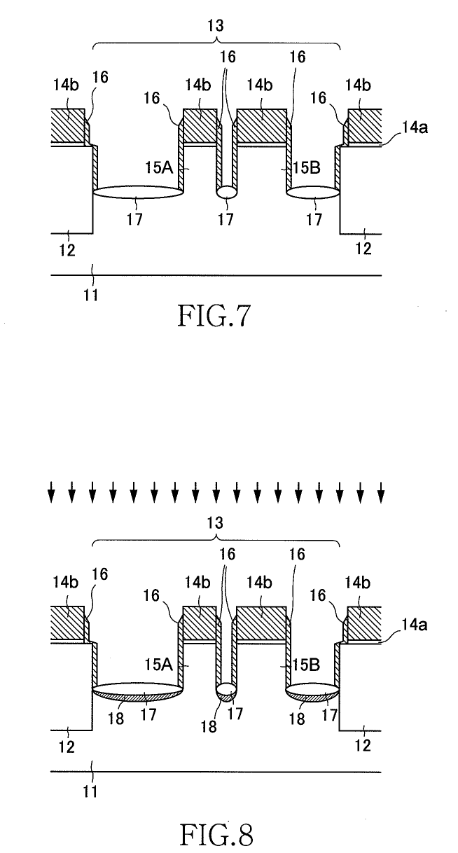

Next, a silicon oxide film 17 is formed by thermal oxidation on the exposed surface of the active region 13 (that is, the bottom surface of the active region 13) (FIG. 7). In this case, the upper surfaces and the side surfaces of the first and second silicon pillars 15A and 15B are covered by the hardmask 14 and the sidewall insulation film 16, respectively, and therefore are not thermally oxidized. While not particularly limited, preferably, a thickness of the silicon oxide film 17 is about 30 nm.

Next, the first diffusion layer 18 is formed at the lower parts of the first and second silicon pillars 15A and 15B, respectively (FIG. 8). The first diffusion layer 18 can be formed by ion-implanting an impurity having conductivity type opposite to that of the impurity in the silicon substrate, via the silicon oxide film 17 formed on the surface of the active region 13.

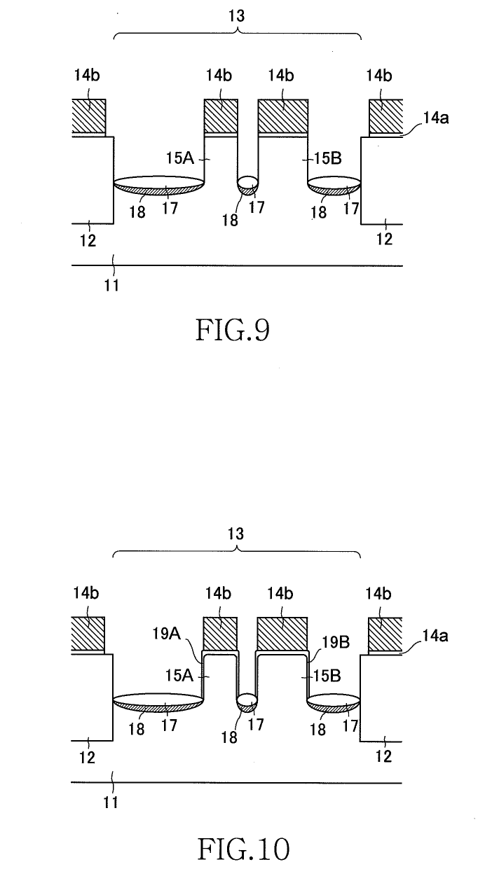

Next, the sidewall insulation film 16 is removed by wet etching (FIG. 9). As a result, the silicon oxide film 17 formed on the bottom surface of the active region 13 and the side surfaces of the first and second silicon pillars 15A and 15B become in the exposed state. The upper surfaces of the first and second silicon pillars 15A and 15B are kept covered by the hardmask 14 as a cap insulation film.

Next, the gate insulation films 19A and 19B are then simultaneously formed on the side surfaces of the first and second silicon pillars 15A and 15B with remaining the hardmask 14 (FIG. 10). The gate insulation films 19A and 19B can be formed by thermal oxidation, and, preferably, their thicknesses are about 5 nm.

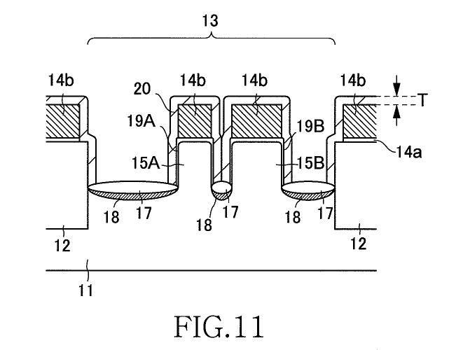

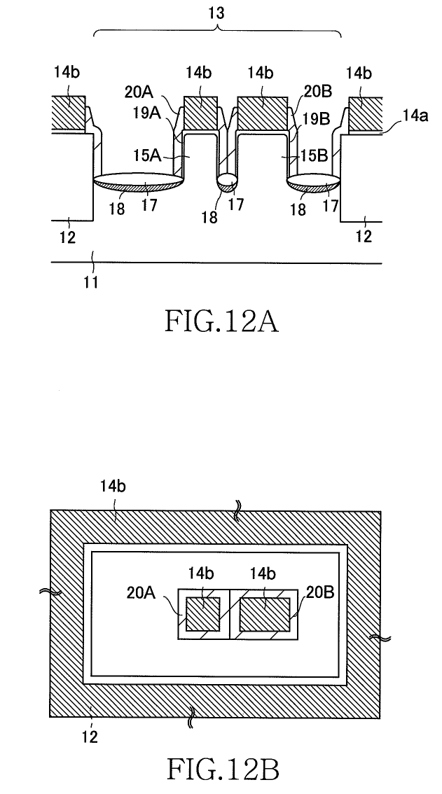

Next, the gate electrodes 20A and 20B made of a polycrystalline silicon film are formed. The gate electrodes 20A and 20B can be formed by forming the polycrystalline silicon film 20 having a thickness T of about 30 nm on the entire surface of the substrate by the CVD method with remaining the hardmask 14 (FIG. 11), and then etching back the polycrystalline silicon film (FIGS. 12A and 12B). Consequently, the side surface of the silicon pillar 15A becomes in the state of being covered by the first gate electrode 20A, and the side surface of the silicon pillar 15B becomes in the state of being covered by the second gate electrode 20B. While the polycrystalline silicon film also remains on the side surface of the STI 12, this polycrystalline silicon film does not function as a gate electrode. Further, since the distance L between the first and second silicon pillars 15A and 15B is set smaller than two times the thickness T of the gate electrode 20, the gate electrodes 20A and 20B formed in the gap between the first silicon pillar 15A and the second silicon pillar 15B are in contact with each other.

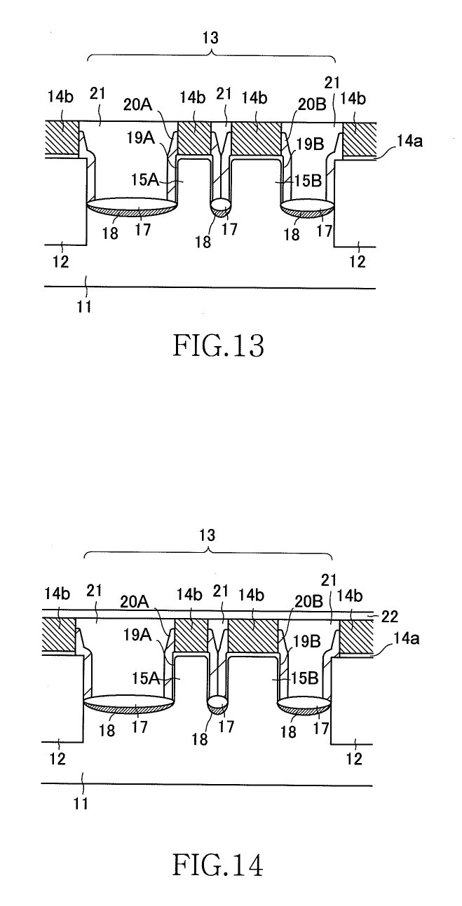

Next, the interlayer insulation film 21 including a silicon oxide film is formed on the entire surface of the substrate, and then the entire surface of the interlayer insulation film 21 is planarized by the CMP method (FIG. 13). In this case, the silicon nitride film 14b serves as a CMP stopper. Therefore, the thickness of the interlayer insulation film 21 can be securely controlled. As a result, the active region 13 becomes in the state of being embedded by the interlayer insulation film 21.

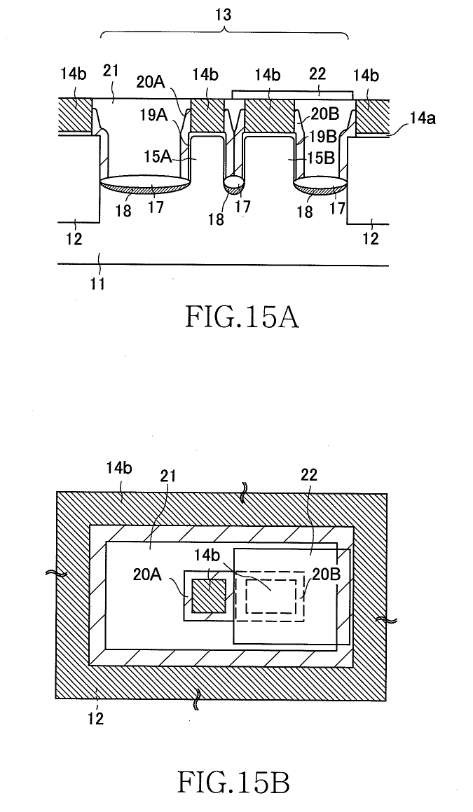

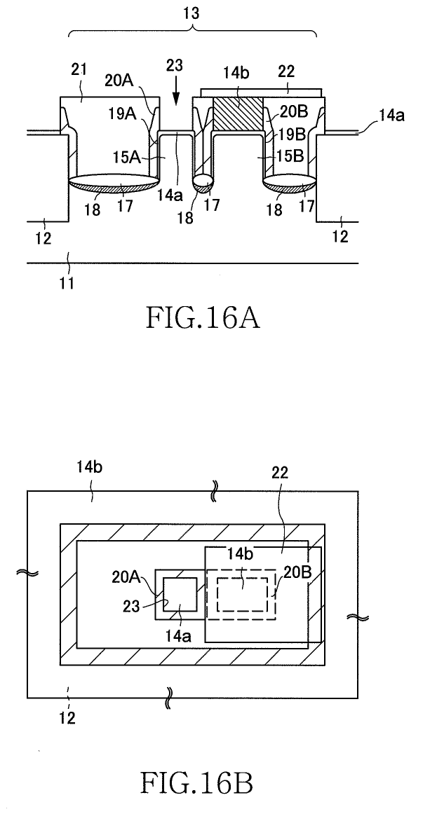

Next, the hardmask 14 provided above the silicon pillar 15A is selectively removed, thereby forming the through-hole (opening) 23. In forming the through-hole 23, a mask oxide film 22 including a silicon oxide film is first formed on the entire surface of the substrate (FIG. 14). The mask oxide film 22 can be formed by the CVD method. Preferably, a thickness of the mask oxide film 22 is about 5 nm. Next, the mask oxide film 22 is patterned so that the silicon nitride film 14b formed above the first silicon pillar 15A is exposed and the silicon nitride film (cap insulation film) 14b above the second silicon pillar 15B is protected (FIGS. 15A and 15B). Thereafter, the exposed silicon nitride film 14b is removed by dry etching or wet etching, thereby forming the through-hole 23 having the silicon oxide film 14a as a bottom surface (FIGS. 16A and 16B).

The through-hole 23 is formed by removing the silicon nitride film 14b used as a mask to form the silicon pillar 15A, and is, therefore, formed in self-alignment to the silicon pillar 15A. Consequently, the inner wall surface of the through-hole 23 and the external periphery of the silicon pillar 15A are on the same surface.

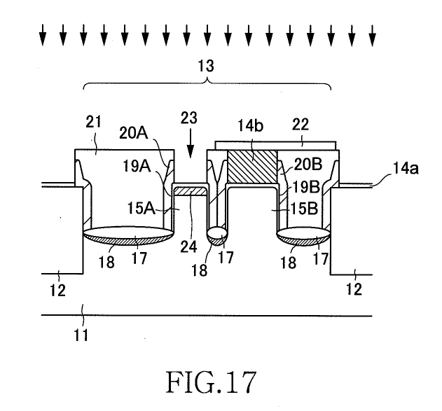

Next, the LDD region 24 is formed on the upper part of the first silicon pillar 15A (FIG. 17). The LDD region 24 can be formed by shallowly ion-implanting an impurity of low concentration having conductivity type opposite to the impurity in the silicon substrate, via the silicon oxide film 14a formed on the upper part of the first silicon pillar 15A.

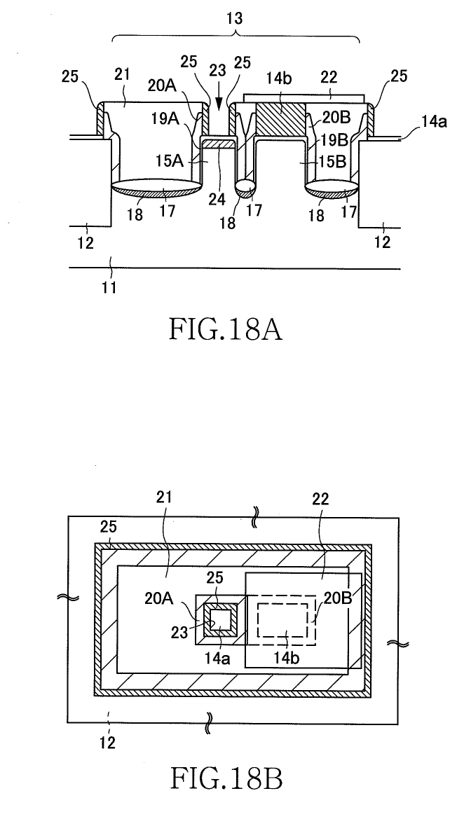

Next, the sidewall insulation film 25 is formed on the inner wall surface of the through-hole 23 (FIG. 18). The sidewall insulation film 25 can be formed by forming a silicon nitride film on the entire surface of the substrate, and then etching back the silicon nitride film. While not particularly limited, preferably, a thickness of the silicon nitride film is about 10 nm. In this way, the sidewall insulation film 25 is formed on the inner wall surface of the through-hole 23, and the through-hole 23 is formed by removing the silicon nitride film 14b as a hardmask used to form the silicon pillar 15A. Therefore, the position of the external periphery of the cylindrical sidewall insulation film 25 and the position of the external periphery of the silicon pillar 15A coincides with each other. While the silicon nitride film is also formed on the external periphery of the active region 13, this silicon nitride film does not function as a sidewall insulation film.

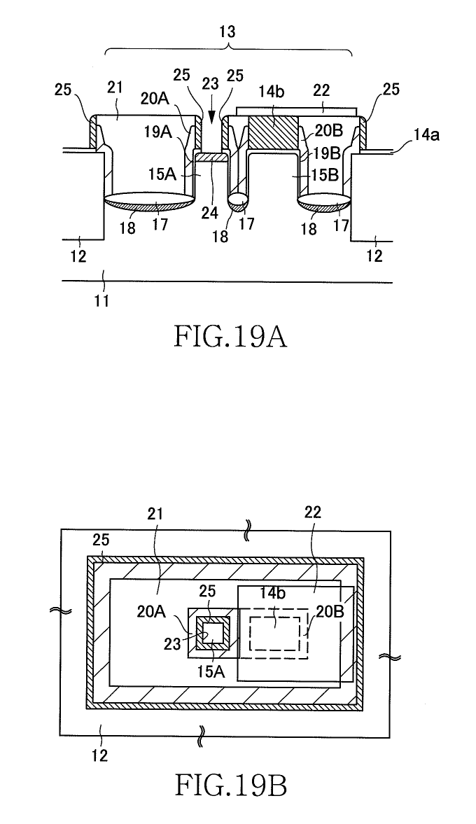

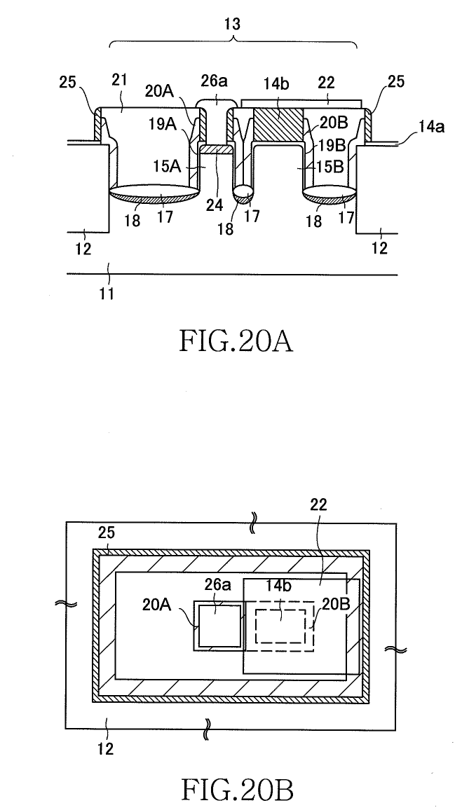

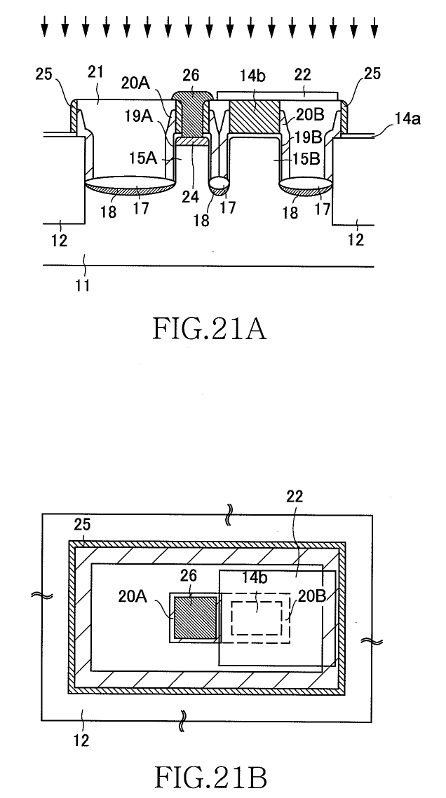

Next, the second diffusion layer 26 is formed on the upper part of the first silicon pillar 15A. In forming the second diffusion layer 26, an opening is formed on the silicon oxide film 14a at the bottom surface of the through-hole, thereby exposing the upper surface of the first silicon pillar 15A (FIGS. 19A and 19B). A silicon epitaxial layer 26a is formed inside the through-hole 23 by a selective epitaxial growth method (FIGS. 20A and 20B). A monocrystalline silicon therefore grows. Thereafter, an impurity of high concentration having conductivity type opposite to that of the impurity in the silicon substrate is ion-implanted into the silicon epitaxial layer 26a, thereby forming the second diffusion layer 26 (FIGS. 21A and 21B). As a result, the second diffusion layer 26 is formed in self-alignment to the first silicon pillar 15A.

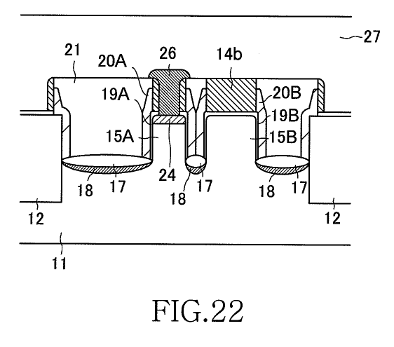

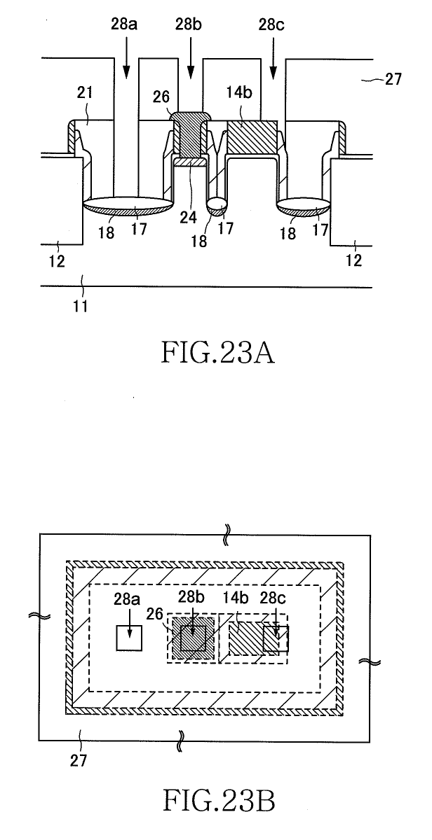

Next, the interlayer insulation film 27 is formed on the entire surface of the substrate (FIG. 22), and then a first to third contact-holes 28a to 28c are formed by patterning (FIGS. 23A and 23B). The first contact-hole 28a is formed in a vacant region within the active region 13 provided adjacent to the first silicon pillar 15A, and reaches the first diffusion layer 18 piercing through the interlayer insulation films 27, 21, and 17. The second contact-hole 28b is formed right above the first silicon pillar 15A, and reaches the second diffusion layer 26 piercing through the interlayer insulation film 27. The third contact-hole 28c is formed above the second silicon pillar 15A, not right above the second silicon pillar 15A, and reaches the second gate electrode 20B piercing through the interlayer insulation films 27 and 21. Particularly, the third contact-hole 28c is preferably connected to a position opposite to the position of connection with the first gate electrode 20A, out of the second gate electrode 20B formed around the second silicon pillar 15B. According to this structure, an interval between the second contact-hole 28b and the third contact-hole 28c can be increased. Therefore, sufficient margin can be secured.

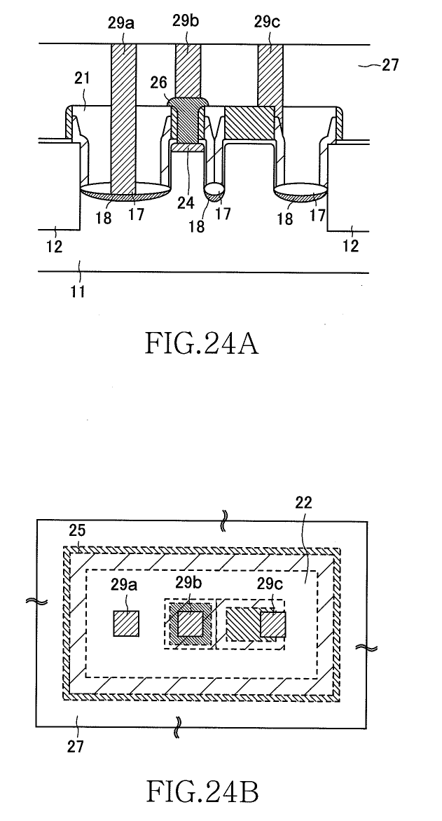

Next, polycrystalline silicon is filled into the first to third contact-holes 28a to 28c, thereby forming the first to third contact-plugs 29a to 29c (FIG. 24). The first contact-plug (the first diffusion layer contact) 29a is connected to the first diffusion layer 18, the second contact-plug (the second diffusion layer contact) 29b is connected to the second diffusion layer 26, and the third contact-plug (the gate contact) is connected to the second gate electrode 20B.

Finally, the wiring layer 30 is formed on the upper end part of the first to third contact-plugs 29a to 29c, thereby completing the semiconductor device 10 according to the present embodiment (FIGS. 1A and 1B).

As explained above, according to the method of manufacturing the semiconductor device 10 of the present embodiment, the first and second silicon pillars 15A and 15B are simultaneously formed using a hardmask. Therefore, the interval (distance L) between the two silicon pillars can be controlled in high precision, and the gate electrodes formed on the silicon pillars can be securely connected to each other. Consequently, the gate contact can be secured without performing photolithography to the first gate electrode 20A having a three-dimensional structure. The gate electrodes 20A and 20B are formed by leaving the hardmask 14 used to form the silicon pillars 15A and 15B, and then, the hardmask 14 on the first silicon pillar 15A is removed. Therefore, the through-hole 23 can be formed in self-alignment at the upper part of the first silicon pillar 15A. Consequently, by forming the second diffusion layer 26 within the through-hole 23, the second diffusion layer 26 can be formed in self-alignment to the first silicon pillar 15A.

Although it is not particularly limited in the present invention, the semiconductor device 10 according to the present embodiment can be used as a cell transistor of a DRAM.

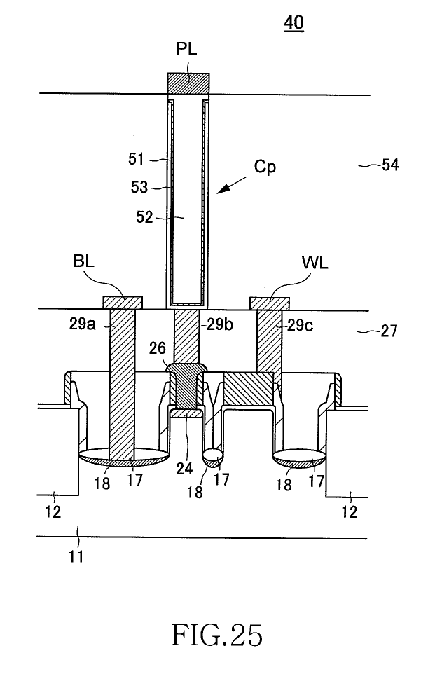

FIG. 25 is a schematic cross-sectional view of a semiconductor device according to another preferred embodiment of the present invention. This embodiment is an example that the semiconductor device 10 is used as a cell transistor of a DRAM.

As shown in FIG. 25, a semiconductor device 40 according to the present embodiment is a DRAM cell using a vertical transistor, and a cell capacitor Cp is formed above a cell transistor Tr. A configuration of the cell transistor is similar to that of the transistor shown in FIG. 1.

The capacitor Cp includes a cylinder-type lower electrode 51, a pillar-type upper electrode 52 connected to a reference potential wiring PL, and a capacitance insulation film 53 provided between the lower electrode 51 and the upper electrode 52. The lower electrode 51 is formed within a cylinder hole piercing through the interlayer insulation film 54, and is connected to the second diffusion layer 26 via the storage node contact 29b. A part of the wiring layer 30 connected to the first diffusion layer 18 is used as a bit line BL, and a part connected to the second gate electrode 20B is used as a word line WL.

As described above, according to the semiconductor device 40 of the present invention, a very compact DRAM cell using a vertical transistor can be realized.

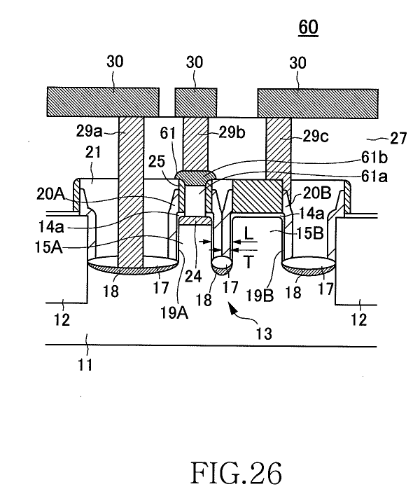

FIG. 26 is a schematic cross-sectional view showing a semiconductor device according to another preferred embodiment of the present invention.

In the semiconductor device 60 according to this embodiment, a lower region 61a of the conductive film 61 connected to the upper part of the silicon pillar 15A has the same conductivity type as that of the silicon substrate, and a upper region 61b of the conductive film 61 has an opposite conductivity type to that of the silicon substrate. Thus, among the conductive film 61, the lower region 61a serves as a part of the channel, and the upper region 61b serves as the second diffusion layer. In the semiconductor device 60, a LDD region at the upper part of the silicon pillar 15A is omitted. Other parts are the same as those of the semiconductor device 10 shown in FIG. 1 and therefore the same reference numerals are given to the same elements, and redundant explanations thereof will be omitted.

The above structure can be obtained by ion-implanting shallowly an impurity having the same conductivity type as the silicon substrate in a step shown in FIG. 17, and ion-implanting deeply an impurity having the same conductivity type as the silicon substrate and ion-implanting shallowly an impurity having an opposite conductivity type to the silicon substrate in a step shown in FIG. 21.

According to this embodiment, a transistor having a so-called offset structure can be realized.

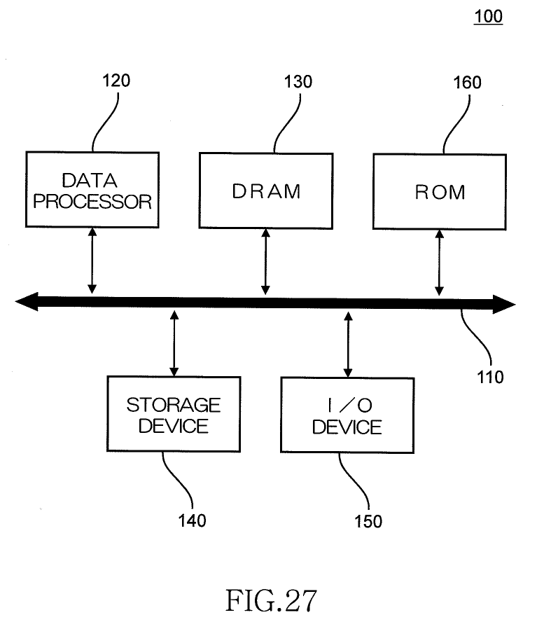

FIG. 27 is a block diagram showing a configuration of a data processing system 100 using a semiconductor device according to the preferred embodiment of the present invention, wherein a DRAM is applied to the semiconductor device of this embodiment.

As shown in FIG. 27, the data processing system 100 includes a data processor 120 and semiconductor device (DRAM) 130 according to the preferred embodiment connected to each other via a system bus 110. The data processor 120 can be selected from at least a microprocessor (MPU) and a digital signal processor (DSP). In FIG. 27, although the data processor 120 and the molecular battery memory device 130 are connected via the system bus 110 in order to simplify the diagram, they can be connected via not the system bus 110 but a local bus.

Further, in FIG. 27, although only one set of system bus 110 is employed in the data processing system 100 in order to simplify the diagram, a serial bus or a parallel bus connected to the system bus 110 via connectors can be provided. As shown in FIG. 27, a storage device 140, an I/O device 150, and a ROM 160 are connected to the system bus 110. However, they are not essential element for the data processing system 100.

The storage device 140 can be selected from at least a hard disk drive, an optical disk drive, and flash memory device. The I/O device 150 can be selected from a display device such as a liquid crystal display (LCD) and an input device such as a key board or a mouse. The I/O device 150 can consists of either input or output device. Further, although each one element is provided as shown in FIG. 27, two or more same elements can be provided in the data processing system.

The present invention has thus been shown and described with reference to specific embodiments. However, it should be noted that the present invention is in no way limited to the details of the described arrangements but changes and modifications may be made without departing from the scope of the appended claims.

For example, the second silicon pillar as the dummy silicon pillar is provided adjacent to the first silicon pillar as the transistor pillar. However, such a dummy silicon pillar is not essential in the present invention.

Further, in the above embodiments, the first and second silicon pillars have approximately rectangular shapes. While both silicon pillars have similar flat shapes, the shapes are not limited to these in the present invention, and various shapes are considered. For example, silicon pillars having a strip shape in the flat surface direction can be used.

In the above embodiments, the silicon epitaxial layer 26a is formed within the through-hole, and ion-implantation into this silicon epitaxial layer 26a is performed, thereby forming the second diffusion layer 26. However, the present invention is not limited to this process. For example, a silicon film doped with an impurity can be embedded into the through-hole to form the second diffusion layer 26. However, when the selective epitaxial growth method is used, continuity of crystal can be secured, and more satisfactory transistor characteristic can be obtained. In the above embodiments, while the first silicon pillar 15A and the second diffusion layer 26 are configured by separate parts, the second diffusion layer 26 can be formed within the first silicon pillar 15A.

What is claimed is:

1. A semiconductor device comprising:
a silicon pillar formed substantially perpendicular to a main surface of a substrate;
a gate electrode covering a side surface of the silicon pillar via a gate insulation film;
a conductive layer provided on an upper part of the silicon pillar; and
a cylindrical sidewall insulation film intervening between the conductive layer and the gate electrode so as to insulate therebetween.

2. The semiconductor device as claimed in claim 1, wherein an internal periphery of the side wall insulation film is in contact with the conductive layer, and an external periphery of the side wall insulation film is in contact with the gate electrode.

3. The semiconductor device as claimed in claim 1, wherein a planar position of an external periphery of the sidewall insulation film and a planar position of an external periphery of the silicon pillar substantially coincide with each other.

4. The semiconductor device as claimed in claim 1 further comprising a protective insulation film having an opening and intervening between the sidewall insulation film and the silicon pillar.

5. The semiconductor device as claimed in claim 1, wherein
the conductive layer includes a silicon material,
a center part of the silicon pillar has a first conductivity type,
a lower part of the silicon pillar has a second conductivity type opposite to the first conductivity type, and
at least a part of the conductive layer has the second conductivity type.

6. The semiconductor device as claimed in claim 5, wherein the upper part of the silicon pillar is served as a LDD region having the second conductivity type.

7. The semiconductor device as claimed in claim 5, wherein the upper part of the silicon pillar and an lower part of the conductive layer have the first conductivity type, and an upper part of the conductive layer has the second conductivity type.

8. The semiconductor device as claimed in claim 5, wherein the conductive layer is made of a monocrystalline silicon including a dopant.

9. A method of manufacturing a semiconductor device comprising:
a first step of forming a silicon pillar on a substrate by using a hardmask;
a second step of forming a gate insulation film on a side surface of the silicon pillar without removing the hardmask;
a third step of forming a gate electrode covering a side surface of the silicon pillar via the gate insulation film without removing the hardmask;
a fourth step of removing the hardmask remaining on a upper part of the silicon pillar, thereby forming a through-hole;
a fifth step of forming a sidewall insulation film on a inner wall of the through-hole; and
a sixth step of forming a conductive film in a space surrounded by the sidewall insulation film.

10. The method of manufacturing a semiconductor device as claimed in claim 9, wherein the third step is performed by forming the gate electrode material on an entire surface of the substrate, and removing a part of the gate electrode material formed on a surface parallel to the substrate by etching back.

11. The semiconductor device as claimed in claim 9 further comprising:
a seventh step of forming a interlayer insulation film on entire surface of the substrate,
an eighth step of exposing the hardmask by removing an upper part of the interlayer insulation film, wherein the seventh and eighth steps are performed after the third step and before the fourth step.

12. The semiconductor device as claimed in claim 9, wherein the sixth step is performed by an epitaxial growth method.

13. The semiconductor device as claimed in claim 9 further comprising a step of forming a first diffusion layer on a lower part of the silicon pillar after the first step and before the second step.

14. The semiconductor device as claimed in claim 13 further comprising a step of forming a second diffusion layer at least at a part of the conductive film after the sixth step.

15. The semiconductor device as claimed in claim 14 further comprising a step of forming a LDD region on the upper part of the silicon pillar after the sixth step and before the sixth step.

16. The semiconductor device as claimed in claim 14 further comprising a step of forming a part of a channel region at a lower part of the conductive film.

17. The semiconductor device as claimed in claim 1 further comprising a capacitor connected to the conductive layer.

18. A data processing system comprising a processor and a semiconductor device coupled to the processor, wherein the semiconductor device includes:
a silicon pillar formed substantially perpendicularly to a main surface of a substrate;
a gate electrode covering a side surface of the silicon pillar via a gate insulation film;
a conductive layer provided on an upper part of the silicon pillar; and
a cylindrical sidewall insulation film intervening between the conductive layer and the gate electrode so as to insulate therebetween.
